(19) United States
(12) Patent Application Publication
(10) Pub. No.: US 2003/0102159 A1
(43) Pub. Date: Jun. 5, 2003

(54) Optimum power and ground bump pad and bump patterns for flip chip packaging

(76) Inventor: Mike C. Loo, San Jose, CA (US)

Correspondence Address: Corporate Patent Counsel, Philips North America Corporation, 580 White Plains Road, Tarrytown, NY, 10591, US

(21) Appl. No.: 10/001,271

(22) Filed: Dec. 4, 2001

(51) Int. Cl. H05K 1/11; H01R 12/04

(52) U.S. Cl. 174/262; 174/255; 174/260

(57) ABSTRACT

Previously, drilled vias were formed in multilayer substrates, interconnecting all layers. The positioning of flip chip bump pads on the substrate has been non-determinate. With the more recent use of microvias, which connect only two adjacent layers, non-determinate positioning of bump pads results in inefficient connection and reduces the routing efficiency and electrical performance. By designating the position of the power and ground bump pads on the substrate, microvias connect the bump pads directly to the related power or ground plane. Similarly signal bump pads can be directly connected to signal planes, giving improved routing and electrical performance. The signal, power and ground bump pads are in sequential rows, to match the relative positioning of the signal, power and ground planes.

This invention relates to the power and ground bumps on flip chips and bump pads on substrates for the mounting of flip chips thereon, and in particular is concerned with optimizing the power and ground bump and bump pad patterns to provide improved routing and electrical performance.

### BACKGROUND OF THE INVENTION

In the conventional technology for PCB substrate manufacture, the substrate having multiple layers, mechanical drilling was employed to produce vias extending through all layers. The chip has a pattern of bumps formed on its surface, for connection to bump pads on the substrate. The bumps were normally in either orthogonal or staggered patterns. The chips were positioned on the substrate as desired. The circuits on the various layers of the substrate are then designed only to connect to the appropriate vias. Thus, in a four-layer substrate, the top and bottom layers were usually signal planes and the two middle layers were power and ground planes, respectively.

A more recent technology is to use microvias which connect only two adjacent layers. With this technology, the location of the power and ground bump pads on a die will influence the routing and electrical performance of the substrate. The present non-selective positioning of power and ground bump pads on the substrate prevents obtaining optimum routing and electrical performances.

### DESCRIPTION OF THE INVENTION

In a PCB substrate, as used for flip chip assemblies or packaging, there are several layers, with two of the layers reserved for power and ground planes respectively. The positioning of power and ground bumps on the chip are normally in a predetermined location. The layers are interconnected by vias and previously the vias were produced by through drilling to provide connections to all layers. The circuit patterns on the various layers, or planes, are arranged such that connection occurs at the appropriate vias to connect to appropriate bump pads and bumps. By using microvias, interconnecting only two adjacent layers, the positioning of the chip power and ground bumps influences routing density and electrical performance. By designating appropriate patterning of the bump pads on the substrate, improved routing and electrical performance is obtained.

Thus, with the present invention, a substrate, for flip chip packaging, has a plurality of layers, providing a power plane, a ground plane and at least one signal plane. Power, ground and signal bump pads are formed on one surface of the substrate, for example, the top surface. The power and ground bump pads extend in rows across the substrate at designated positions. Microvias at the designated positions connect the power bump pads and ground bump pads respectively to the power and ground planes. Further microvias connect signal bump pads directly to a signal plane. On the flip chip power and ground pads extend in parallel rows in a designated position, to match the rows of power and ground bump pads.

### BRIEF DESCRIPTION OF THE DRAWINGS

FIG. 1 is a cross-section through a four-layer substrate, illustrating through layer connections with drilled vias in a conventional PCB structure;

FIG. 2 is a cross-section through a four-layer substrate, illustrating the more recent microvias connecting only two adjacent layers; and with non-designated bumps and bump pad locations;

FIG. 3 is a cross-section through a four-layer substrate, having a designated bump and bump pad patterns, with appropriate microvia connections;

FIGS. 4(a) and 4(b) illustrate, in plan view, two bump patterns on a flip chip, in accordance with the invention.

### DETAILED DESCRIPTION OF THE DRAWINGS

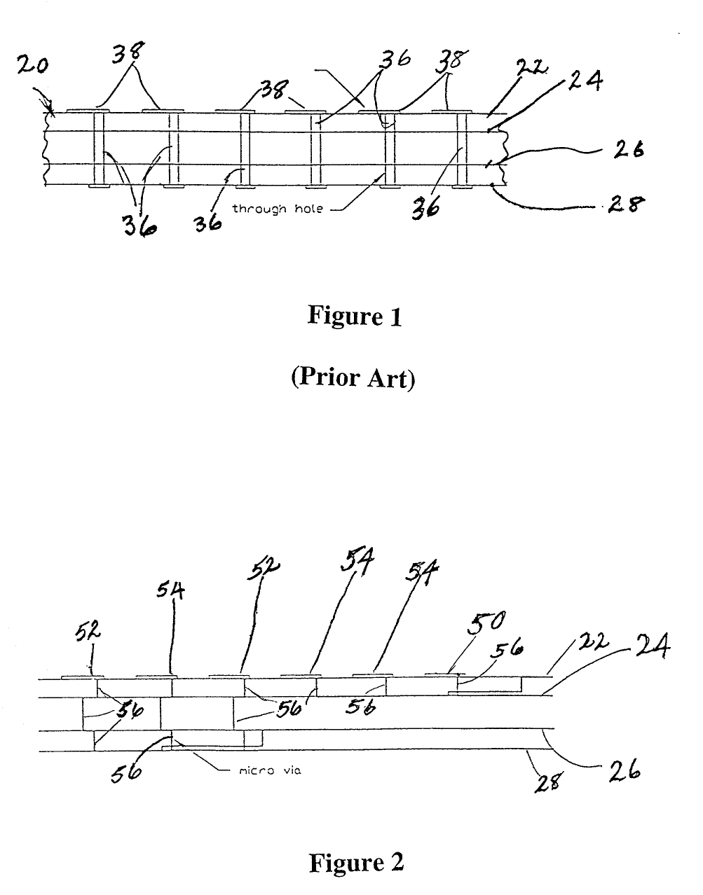

FIG. 1 illustrates the interconnection through a four-layer substrate or PCB, indicated generally at 20. The four layers are indicated at 22, 24, 26 and 28. Normally the power and ground planes are the second and third layers 24 and 26. The first and fourth layers form the signal layers.

In a conventional printed circuit board, all the layers are interconnected by drilled vias 36 which extend through to all layers. Flip chip bump pads 38 extend on the first layer 22 at the end of each via, providing connection thereto. With this arrangement, there are no designated chip bump or bump pads specific for ground, power or signal.

The circuit patterns both on the chip and the substrate are such that certain bumps and bump pads cooperate to provide the desired connection between flip chip and substrate. The pattern of bumps on the flip chip and bump pads on the substrate are not in any designated form. Thus there is no designated pattern for the ground and power bumps and bump pads. This is not of any consequence with through vias as in FIG. 1. The positioning of related bumps and bump pads is dependent upon the chip circuitry and associated substrate circuitry.

In printed circuit boards with microvias, for optimum routing and electrical performance it is necessary to position the chip bumps for power and ground bumps at specific positions. Without this, optimum results are not obtained. Thus, as seen in FIG. 2 for example, because of the positioning of the power and ground bump pads 50 and 52 and signal pads 54, direct connection between a pad and the required plane does not occur. Some of the signals need to go to the second layer and back to the first layer through microvias. Routing will be more difficult and electrical performance less than optimum as there is no power or ground plane for those signals to refer to.

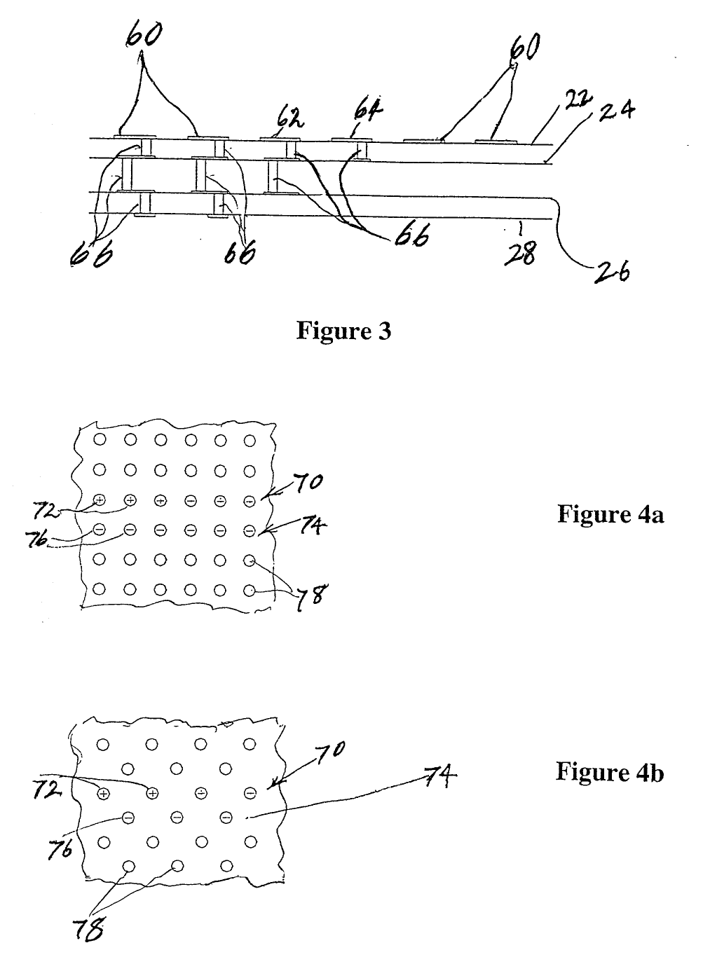

Ideally, it is desirable that connections from a bump pad to a plane be made in as direct a manner as possible. FIG. 3 illustrates one such arrangement. In this arrangement, the first and second rows of flip chip bumps, signal bumps, will connect to the first and second rows of bump pads 60, which in turn connect to the first layer 22, having a signal plane. The next two rows of bump pads are power and ground bump pads 62 and 64 respectively, the ground bump pads being connected directly to the ground plane at the second layer 24 and the power bump pads connected directly to the power plane at the third layer 26, by microvias 66. It will be seen that the rows of power and ground bump pads, 62 and 64, and the signal bump pads 60, are in sequence, to match the positioning of the signal, power and ground planes 22, 24 and 26. This is the desirable arrangement. Further rows of signal bump pads connect via microvias 66 directly to the signal plane at the fourth layer. It will be seen that it is not necessary to provide for connections back through layers, as occurs in FIG. 2. Thus routing is improved and electrical performance improved.

The bumps on the flip chip are similarly designated. This is illustrated in FIGS. 4(a) and 4(b). Chip bumps are normally arranged either in an orthogonal pattern, as in FIG. 4(a) or in a staggered pattern, as in FIG. 4(b). Whereas in the previous arrangements with through vias, no particular pattern of power and ground bumps occurred in the present invention the power and ground bumps extend in two adjacent parallel rows—row 70 for power for example, with bumps 72 and now 74 for ground with bumps 76. Signal bumps 78 are also provided.

The power and ground bumps 72, 76 are positioned to connect to the power and ground bump pads 62 and 64 on the substrate and thus directly to the power and ground planes by the microvias 66.

Thus, it is arranged that the ground and power bumps on the chip and bump pads on the substrate are in designated rows on the chip and on the substrate so as to form cooperating connections. Microvias are formed in the substrate to provide direct connection to the respective ground and power planes. The signal bumps on the flip chip, connect directly to one signal plane or via microvias directly to the other signal plane.

The circuit diagrams for the various planes are designed so that appropriate connections are made to the microvias and thus to the appropriate bump pads.

Often, in electronic component design, computers are used to automate much of the design process. For example, computers automatically route interconnects within a package or an integrated circuit, within a board for use in a hybrid circuit or within a printed circuit board for other applications. The use of computers allows for repeatable use of templates, automated routing, automated transfer of programming data to a manufacturing system, repeatable production results, automated parts lists for PCB manufacturing, and so forth. This highly automated approach to design is considered desirable.

The present invention is also implementable on a computer or other processing system. A program is typically delivered stored on a non-volatile storage medium such as a CD-ROM, a DVD-ROM, a floppy disk, etc. The program is input to the computer system in a process typically referred to as installation. Once installed, the program is executed. According to the present invention, execution of the program results in programming for the manufacturing process for forming a flip chip package in accordance with the above description. Alternatively, execution of the program provides a template that results in programming for the manufacturing process for forming in a flip chip package in accordance with the above description.

Of course, when the computer is coupled with a manufacturing system, execution of the program results in the actual flip chip package since the program provides instructions to the manufacturing system for forming the package. As such, many embodiments of the invention may be envisioned for forming a flip chip package, a representation of same for use in manufacturing, or for providing a template of a representation of same for use in manufacturing.

It is possible to provide some other arrangement of the various planes, in which case the relative positioning of power and ground bump pads is such as to provide the direct connection to the power and ground planes.

1. A substrate for flip chip packaging, comprising:
a multiple layer substrate having a first layer forming a signal plane and second and third layers beneath said first layer, said second and third layers forming selectively power and ground planes;
power, ground and signal bump pads on said first layer, said power and ground bump pads extending in parallel rows in a designated position; and
microvias connecting said power bump pads directly to said power plane and said ground bump pads directly to said ground plane.

2. A substrate as claimed in claim 1, including a further signal plane below said power and ground planes, and microvias connecting related signal bump pads on said first layer to said further signal plane.

3. A substrate as claimed in claim 1, said first layer on a top surface of said substrate.

4. A substrate as claimed in claim 2, said further signal plane on a bottom surface of said substrate.

5. A substrate as claimed in claim 1, said signal bump pads extending in parallel rows; said rows of signal power and ground bump pads positioned sequentially in the order of positioning of said signal, power and ground planes.

6. A flip chip package comprising a flip chip mounted on a multistage substrate having a first, signal, layer, a power layer having a power plane, and a ground layer having a ground plane beneath said signal layer;
power, ground and signal bump pads formed on said first layer, said power and ground bump pads extending in parallel rows in a designated position;
microvias connecting said power and ground bump pads directly to said power and ground planes;
power and ground bumps on said flip chip, extending in parallel rows in a designated position, and connected to said power and ground bump pads;
signal bumps on said flip chip connected to said signal bump pads.

7. A flip chip package as claimed in claim 6, including a further layer forming a further signal plane beneath said power and ground planes, and microvias connecting signal bump pads on said first layer to said further signal plane.

8. A flip chip package as claimed in claim 6, said first layer on a top layer of said substrate.

9. A flip chip package as claimed in claim 7, said further signal plane on a bottom surface of said substrate.

10. A flip chip package as claimed in claim 6, said signal bump pads extending in parallel rows, said rows of signal, power and ground bump pads positioned sequentially in the order of positioning of said signal power and ground planes.

11. A method of making a substrate for flip chip packaging, comprising:
forming signal, power and ground planes at various layers of a multistage substrate;
forming power and ground bump pads on a top layer of said substrate, said bump pads extending in parallel rows at a designated position; and,
forming microvias to connect said power bump pads directly to said power plane and to connect said ground bump pads directly to said ground plane.

12. A method as claimed in claim 11, including forming signal bump pads, extending in rows parallel to said power and ground bump pad rows, said rows of signal, power and ground bump pads formed sequentially in the order of positioning of said signal, power and ground planes.

13. A method as claimed in claim 11, wherein the method is implemented in part on a processor forming part of a computer system.

14. A method as claimed in claim 12, wherein the computer system provides data for a layout for a substrate for flip chip packaging, the data indicative of the layout and for use in manufacturing of the substrate for flip chip packaging.

15. A machine readable storage medium comprising a plurality of instructions stored therein for performing the steps of:
forming representations of signal, power and ground planes at various layers of a virtual multistage substrate;
forming representations of power and ground bump pads on a top layer of said substrate, said bump pads extending in parallel rows at a designated position;
forming representations of microvias to connect said power bump pads directly to said power plane and to connect said ground bump pads directly to said ground plane and,
providing the representations in a format for use in a manufacturing process to produce to produce a product based on the representations.

16. A machine readable storage medium as defined in claim 15 comprising:
a computer for reading the machine readable storage medium and for performing the instructions stored therein.

17. A machine readable storage medium as defined in claim 16 comprising:
a manufacturing system responsive to a representation received from the computer for producing a flip chip package in accordance with the representation.
